(19) United States
(12) Patent Application Publication
(10) Pub. No.: US 2007/0006055 A1
(43) Pub. Date: Jan. 4, 2007

(54) Method for expediting defect detection and burning

(75) Inventors: Ping-Sheng Chen, Chung Pu Hsiang (TW); Hong-Ching Chen, Feng Shan City (TW)

Correspondence Address: BIRCH STEWART KOLASCH & BIRCH, PO BOX 747, FALLS CHURCH, VA, 22040-0747, US

(73) Assignee: MEDIATEK INCORPORATION

(21) Appl. No.: 11/477,926

(22) Filed: Jun. 30, 2006

(30) Foreign Application Priority Data
Jul. 1, 2005 (TW) 94122453

(51) Int. Cl. G11C 29/00

(52) U.S. Cl. 714/710

(57) ABSTRACT

A method for expediting defect detection and burning used for a rewritable burning system and a rewritable disc detects whether or not a target write-in area contains an unreliable area (or a defect area) during a burning. A target write-in area is sought. Data stored in the target write-in area are read. Whether or not the data are in the unreliable area is detected. The target write-in area is sought. The desired data are written. Whether or not the unreliable aera exists is determined. The desired data stored in the unreliable area are written into a spare area, if the unreliable area exists. Whether or not the burning of all data is completed is determined. The burning is repeated until the burning of all data is completed, if the burning of all data is not completed.

### BACKGROUND OF THE INVENTION

1. Field of the Invention

The present invention relates to a method for expediting defect detection and burning that adopts a rewritable burning technology to detect whether or not a target burning region has an unreliable area during a burning process.

2. Description of Related Art

At present, the specifications of a rewritable disc include CD-RW, DVD+RW, and DVD-RAM. During a data burning process, unknown factors such as scratches and defects may burn data to an unreliable area, which will cause unreadable data in the future or ruin the reliability of data stored in the disc. To guarantee the accuracy of burned data, a prior art defect management system has been developed. After data are burned, the burned data are read and verified. If the burned data cannot be read, then the location of the data is considered a defect area, and the defect area is recorded. Data are written into a blank and defect-free spare area instead of being written in the defect area.

Referring to FIG. 1 for the flow chart of a prior art defect management and burning system, the desired data are divided into a plurality of divisions according to the buffer memory of a burner before carrying out the burning process. The procedure comprises the steps of seeking a target write-in area and writing the desired data (Step 101); seeking the target write-in area and reading the burned data (Step 102); determining whether or not the read data are reliable (Step 103); continuing determining whether or not the burning of data is completed, where reliable data indicate that the burned data are correct (Step 105); burning the data stored in the division into a spare area, where unreliable data indicate the tested data has an error (Step 104); determining whether or not the burning of all data is completed (Step 105); ending the burning procedure, if the burning of data is completed, and continuing the data burning procedure until the burning of all data is completed, if the burning of all data is not completed.

In a prior art burning process, it is necessary to read the burned data again in order to confirm the integrity of the burned data. The required time is illustrated by the following formula, where M stands for the length of burning division depending on each buffer memory, N stands for the length of the desired data, T_{write}_{_{—}}ₛₑₑₖ stands for the time required for a laser pickup head to seek the write-in area before writing data, Speed_{write} stands for the time for writing a unit length of data, T_{read}_{_{—}}ₛₑₑₖ stands for the time required for a laser pickup head to seek the write-in area, and Speed_{read} stands for the time for reading a unit length of data. The formula of the time T for writing data having a length N is given below:
T(N/M)×(T_{write}_{_{—}}ₛₑₑₖ.Speed_{write}×M.T_{read}_{_{—}}ₛₑₑₖ.Speed_{reands for ad}×M).(N/M)×(T_{write}_{_{—}}ₛₑₑₖ.T_{read}_{_{—}}ₛₑₑₖ).N×(Speed_{write}.Speed_{read}) (Formula 1)

To guarantee the accuracy of burning data according to the prior art, the reliability of the data is read and verified after each time of burning, and the unreadable data are written into a blank spare area. Although this method can assure the reliability of the burned data, it wastes time by seeking and reading the data for each burning. As a result, the overall burning process is lengthy, and it is necessary to subdivide the burning into many divisions (it is necessary for a laser pickup head to repeatedly read and burn the data on the disc at least 600/2=300 times for data with a length of 600 MB and a buffer memory of 2 MB) according to the memory size of the burner in order to store the burned data in a limited memory of the burner (which is the buffer memory of the prior art) before verifying the burned data. Such an arrangement results in a poor burning efficiency and a time-consuming and inconvenient application.

### SUMMARY OF THE INVENTION

Therefore, it is a primary objective of the present invention to provide a method for expediting defect detection and burning. The method ensures the reliability of the burned data, and uses a smaller buffer memory. The method according to the present invention is thus faster, and takes up less memory space for burning data, than the prior art.

To achieve the foregoing objective, the invention is used for a rewritable burning system and a rewritable disc. In the burning process, the target write-in area is detected to determine whether or not an unreliable area, or a defect area, exists. If the method for expediting defect detection and burning in accordance with the present invention is used to burn the data of an optical disc, the procedure comprises the following steps. A target write-in area is sought and the data stored in the target write-in area is read. Whether the data fall in an unreliable area is determined. The target write-in area is sought, and desired data is written there into. Whether or not an unreliable area exists is determined. The data stored in the unreliable area are written into a spare area, if an unreliable area exists. Whether or not the burning of data is completed is determined. If the burning of data is not completed, the burning of data is repeated until the burning of all data is completed.

Another method for expediting defect detection and burning according to the present invention used in a blank optical disc comprises the following steps. A target write-in area is sought. Verified data are written there into. The target write-in area is sought. The verification data are read, and whether the verified data are in an unreliable area is determined. The target write-in area is sought, and the desired data are written there into. Whether or not an unreliable area exists is determined. The desired data stored in the unreliable area are written into a spare area, if an unreliable area exists. Whether or not the burning of data is completed is determined. If not complete, the burning of data is repeated until the burning of all data is completed.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a flow chart of a prior art defect management and burning method;

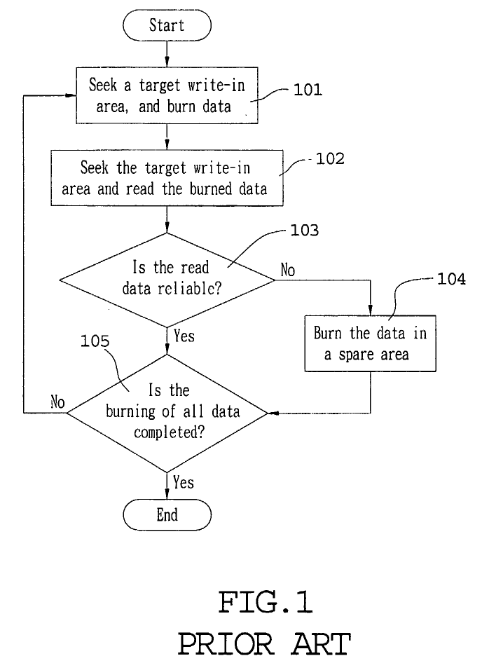

FIG. 2 is a flow chart of a method for expediting defect detection and burning according to a first preferred embodiment of the present invention;

FIG. 3 is a flow chart of a method for expediting defect detection and burning according to a second preferred embodiment of the present invention;

FIG. 4 is a flow chart of a method for expediting defect detection and burning according to a third preferred embodiment of the present invention;

FIG. 5 is a flow chart of a method for expediting defect detection and burning according to a fourth preferred embodiment of the present invention; and

FIG. 6 is a flow chart of a method for expediting defect detection and burning according to a fifth preferred embodiment of the present invention;

### DETAILED DESCRIPTION OF PREFERRED EMBODIMENTS

To make it easier for our examiner to understand the innovative features and technical content, a preferred embodiment is used together with the attached drawings for the detailed description of the invention, but it should be pointed out that the attached drawings are provided for reference and description but not for limiting the present invention. The method of the present invention is used for a rewritable burning system and a rewritable disc including but not limited to CD-RW, DVD-RW, DVD+RW, and DVD-RAM.

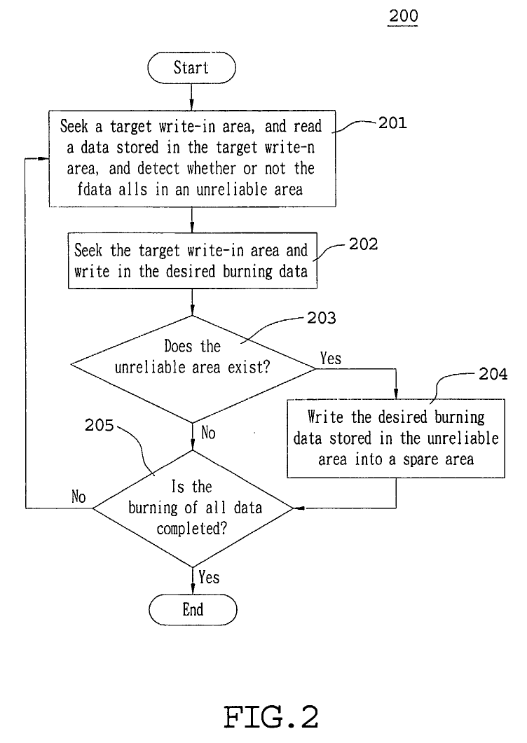

Referring to FIG. 2 for the flow chart of a method for expediting defect detection and burning according to a first preferred embodiment of the present invention, the first preferred embodiment 200 is applicable for a rewritable system when the write-in area already contains data. This embodiment uses the existing data to determine whether or not an unreliable area exists, and does not need to repeatedly read the data during a burning process to determine whether or not the data are reliable. The foregoing unreliable area can be determined by the readability of the data. For example, the original error of a data cannot be corrected by a prior art error correction mechanism, the original error detected by its error correction mechanism is larger than a critical value, or the physical properties of the optical disc determine the unreliable area.

The desired data are divided into divisions according to the buffer memory size of the burner or the computer system, and the data burning process is carried out division by division. The procedure thereof is described as follows.

The burning process starts. The laser pickup head seeks a target write-in area of an optical disc, and reads the data stored in the target write-in area. Whether or not the data are in an unreliable area is detected (Step 201). The laser pickup head then seeks the target write-in area (or target write address), and burns the data into the optical disc (Step 202). Whether or not the unreliable area exists is determined (Step 203). If the unreliable area does not exist, then whether or not the burning of the desired data is completed is determined (Step 205). If the reliable area exists, then the desired data stored in the unreliable area are written into a spare area (Step 204). This spare area exists in a continuous or a discrete form in a blank area of the optical disc, and the spare area can be a reserved area or a random area. Whether or not the burning of all data is completed is determined (Step 205). If not, then the target write-in area is continually sought, the data in the target write-in area are continually written there into, and the unreliable area is continually detected (Step 201). If the burning of all data is completed, then the burning process is terminated.

The time required by the procedure shown in FIG. 2 is given by Formula 2, where M stands for the length of each burning division (depending on the buffer memory size of the burner), N stands for the length of a division of data, T_{write} seek stands for the time for a laser pickup head to seek the write-in area before writing data, Speed_{write} stands for the write-in time per unit data length, T_{read}_{_{—}}ₛₑₑₖ stands for the time for the laser pickup head to seek the write-in area, and Speed_{read} stands for the read-out time per unit data length. The formula for the time T1 of burning a data with a length N is given below:
T1.T_{write}_{_{—}}ₛₑₑₖ.T_{read}_{_{—}}ₛₑₑₖ.N×.Speed_{read}.Speed_{write} (Formula 2)

Compared with Formula 1 of the prior art, the first preferred embodiment 200 of the present invention detects whether or not there is an unreliable area during the burning process, and thus it only takes one read and one write for each seek time during the process of writing a data with a length N. Seeking the target write-in area after a refresh for each section of buffer memory is not necessary. Therefore, the first preferred embodiment 200 can save a multiple of seek time, and the saved time is given as follows:
T.T1=(N/M.1)×(T_{write}_{_{—}}ₛₑₑₖ.T_{read}_{_{—}}ₛₑₑₖ) (Formula 3)
where N/M is a value great than 1, and thus can save time when compared with the prior art.

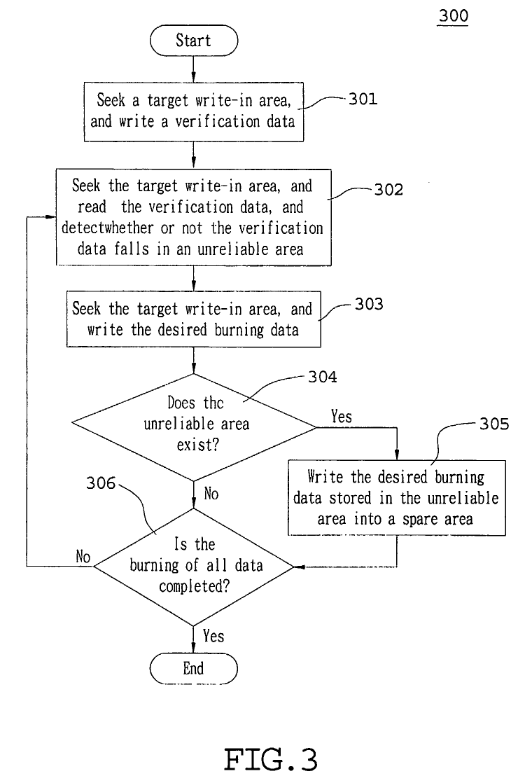

FIG. 3 is a flow chart of a method for expediting defect detection and burning according to a second preferred embodiment of the present invention. The second preferred embodiment 300 is applicable for a rewritable system. The desired burning area has no data yet, and thus this embodiment actively writes verification data into the desired burning area. The content of this verification data is defined in advance in a controller of the burner. Reading the verification data determines whether or not there is an unreliable area, and the procedure of writing the verification data is, for example, a process of formatting a rewritable disc. The burning process of the second preferred embodiment 300 is described as follows.

The burning process starts, and a laser pickup head of a burner seeks a target write-in area (or target write address) of an optical disc. Since the desired burning area has no data yet, verified data are written into the desired burning area (Step 301). The laser pickup head then seeks the target write-in area and reads the verification data, and detects whether or not the verification data has an unreliable area (Step 302). The target write-in area is sought to write the desired data there into (Step 303). Whether or not an unreliable area exists is determined (Step 304). If no unreliable area exists, then whether or not the burning of the desired data is completed is determined (Step 306). If the unreliable area as mentioned in Step 304 exists, then the desired data stored in the unreliable area are written into a spare area (Step 305). The spare area exists in a continuous or discrete form in a blank area of the optical disc, and the spare area is, for example, a reserved area or a random area. Whether or not the burning of all data is completed is determined (Step 306). If the burning of all data is not completed, then the next target write-in area is sought, the verification data in the target write-in area are read, and the unreliable area is detected (Step 302). If the burning of all data is completed, then the burning process is terminated.

The time required for the procedure shown in FIG. 3 is given by Formula 4, where M stands for the length of each burning division (depending on the buffer memory size of the burner), N stands for the length of a division of data, T_{write}_{_{—}}ₛₑₑₖ stands for the time for a laser pickup head to seek the write-in area before writing data, Speed_{write} stands for the write-in time per unit data length, T_{read}_{_{—}}ₛₑₑₖ stands for the time for the laser pickup head to seek the write-in area, and Speed_{read} stands for the read-out time per unit data length. The formula for the time T2 of burning data with a length N is given below:
T2.T_{write}_{_{—}}ₛₑₑₖ×2.T_{read}_{_{—}}ₛₑₑₖ.N×.Speed_{read}.Speed_{write}×2. (Formula 4)

Compared with Formula 1 of the prior art, the preferred embodiment 300 of the present invention writes verification data during the burning process, and thus it has twice as much seek time T_{write}_{_{—}}ₛₑₑₖ and write time Speed_{write} before burning data. This embodiment still can save more time than the prior art that reads the data again after burning data in order to determine if there is an error. The saved time is given as follows:
T.T2=(N/M.1)×(T_{write}_{_{—}}ₛₑₑₖ.T_{read}_{_{—}}ₛₑₑₖ).(T_{write}_{_{—}}ₛₑₑₖ.N×Speed_{write}) (Formula 5)

If N is larger than a specific value or M is smaller than a specific value, then it is faster than the prior art.

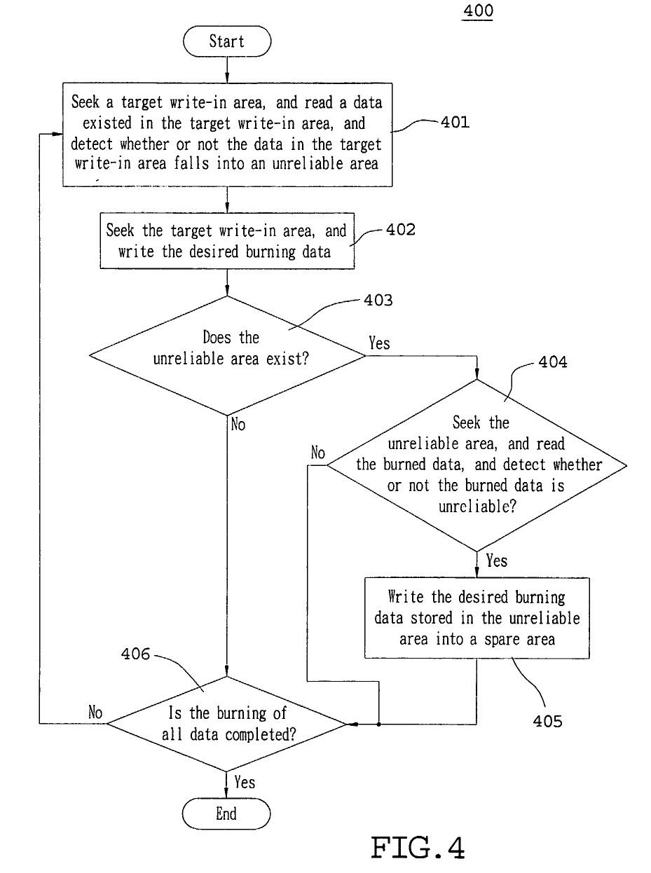

FIG. 4 is a flow chart of a third preferred embodiment of the present invention. The third embodiment 400 is applicable for a rewritable system, where the desired burning area already has data. If this area is determined to be an unreliable area, then the burned data will be read out once again to determine whether or not the area is a defect area. With a reconfirmation procedure, an actual defect area can be detected, so as to avoid any waste of space in a spare area. If a rewritable disc has a quality problem, this method can extend the life of an optical disc.

The burning procedure in accordance with the third preferred embodiment 400 is described as follows.

The burning process starts. The laser pickup head seeks a target write-in area of an optical disc. Since data already exists in the desired burning area, reading out the data originally existing in the desired burning area is used to detect an unreliable area (Step 401). The target write-in area is sought again, and the desired data is written (Step 402). Whether or not an unreliable area exists is determined (Step 403). If there is no unreliable area, then whether or not the burning of data is completed is determined (Step 406). If an unreliable area as described in Step 403 exists, then the target write-in area is sought again and the burned data in the unreliable area is read. Whether or not the burned data in the unreliable area is unreliable is detected in order to make sure the unreliable area is a real defect area (Step 404). If the unreliable area is confirmed as a defect area, then the data stored in the defect area are written into a spare area (Step 405). Determination of whether or not the burning of data is completed is continued (Step 406). If the burning of data is completed, then the burning process is terminated. If not, the next target write-in area is sought and the unreliable area is detected (Step 401), until the burning of all data is completed.

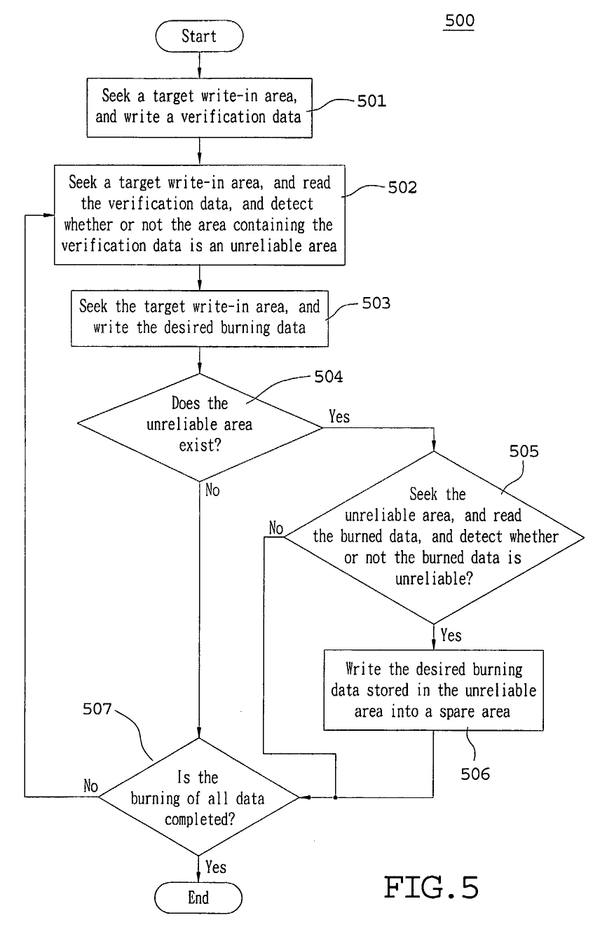

FIG. 5 is a flow chart of a method for expediting defect detection according to a fourth preferred embodiment of the present invention. The fourth preferred embodiment 500 is applicable for a rewritable system where the desired burning area has no data yet. This embodiment thus actively writes verification data into the desired burning area, and the content of this verification data is defined in advance in a controller of the burner. Reading the verification data determines whether or not there is an unreliable area. If the area is determined to be an unreliable area, then the burned data stored in the unreliable area are read once again to determine whether or not the unreliable area is a defect area. With a reconfirmation procedure, a real defect area can be detected, so as to avoid any waste of space in a spare area. If a rewritable disc has a quality problem, this method can extend the life of an optical disc. The foregoing procedure of writing the verification data is, for example, a process of formatting a rewritable disc.

The burning procedure in accordance to the fourth embodiment is described as follows.

The burning process starts, and a laser pickup head of a burner seeks a target write-in area (or target write address) of an optical disc. Since the desired burning area has no data yet, verification data are written into the desired burning area (Step 501). The target write-in area is sought, and the verification data are read. Whether or not the verification data has an unreliable area is detected (Step 502). The target write-in area is sought and the desired data are written (Step 503). Whether or not the unreliable area exists is determined (Step 504). If no unreliable area exists, then whether or not the burning of the desired data is completed is determined (Step 506). If the unreliable area as mentioned in Step 504 exists, then the target write-in area is sought again, and the burned data stored in the unreliable area are read. Whether or not the burned data in the unreliable area are reliable is determined in order to confirm that the unreliable area is a real defect area (Step 305). If the unreliable area is confirmed as a defect area, the data stored in the defect area are written into a spare area (Step 306). The spare area exists in a continuous or discrete form in a blank area of the optical disc, and the spare area is, for example, a reserved area or a random area. Whether or not the burning of all data is completed is determined (Step 507). If the burning is completed, then the burning process is terminated. If the burning is not completed, then the next target write-in area is sought, the verification data in the target write-in area are read, and the unreliable area is detected (Step 501) until the burning of all data is completed.

The foregoing first preferred embodiment 200, second preferred embodiment 300, third preferred embodiment 400, and fourth preferred embodiment 500 are applicable to rewritable optical disk drives. Before burning a data, the procedure of detecting an unreliable area takes place to check if the optical disc has defect areas. Instead of repeatedly burning, reading, and verifying data, or seeking many times, these embodiments not only reduce the burning time, but also write the burned data stored in the unreliable area into a spare area, so as to eliminate the error of writing data into an unreliable area or reading unreadable data.

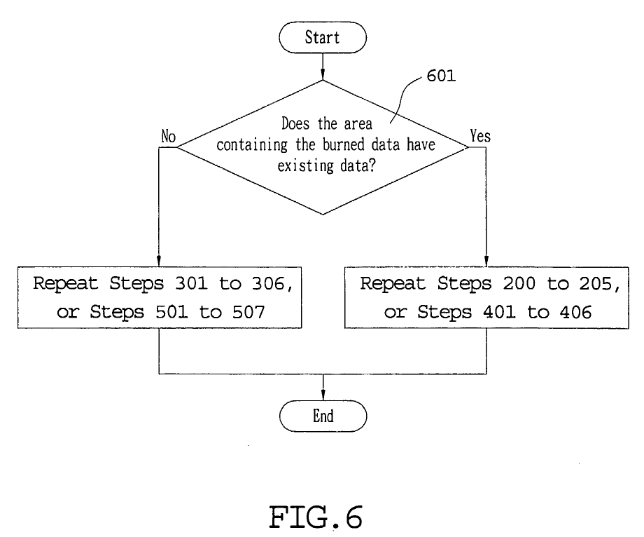

FIG. 6 is a flow chart of a method for expediting defect detection according to a fifth preferred embodiment of the present invention. A section of the optical disk having existing data is used. If a section of the optical disk is blank, whether or not a desired burning area already has data is determined when starting the burning process (Step 601). If the desired write-in area already has data, then the procedure of the first preferred embodiment 100 (refer to Steps 201 to 205 as illustrated in FIG. 2) or the procedure of the third preferred embodiment 400 (refer to Steps 401 to 406 as illustrated in FIG. 4) is adopted. If the desired write-in area has no existing data, the procedure of the second preferred embodiment 300 (refer to Steps 301 to 306 as illustrated in FIG. 3) or the procedure of the fourth preferred embodiment 500 (refer to Steps 501 to 507 as illustrated in FIG. 5) is adopted. In other words, a procedure for determining whether or not a desired write-in area already has existing data is adopted before starting the burning of data, so as to decide an appropriate method for detecting defects and burning.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for expediting defect detection and burning, being used in an optical disc having burned data, the method comprising the steps of:
(a) seeking a target write-in area, reading data stored in said target write-in area, and detecting if said data fall in an unreliable area;
(b) seeking said target write-in area to write desired burning data thereinto;
(c) determining whether or not said unreliable area exists;
(d) writing said desired burning data stored in said unreliable area into a spare area, if said unreliable area as described in step (c) exists; and
(e) determining whether or not the burning of all data is completed, wherein if burning of all data is not completed, then steps (a) to (e) are repeated until the burning of all data is completed.

2. The method for expediting defect detection and burning of claim 1, wherein said step of seeking a target write-in area, and reading data stored in said target write-in area, and detecting if said data fall in an unreliable area makes use of readability of read data to determine said unreliable area.

3. The method for expediting defect detection and burning of claim 1, wherein said step of seeking a target write-in area, and reading data stored in said target write-in area, and detecting if said data fall in an unreliable area determines said unreliable area by the original error of read data being larger than a critical value, said original error being obtained from an error correction mechanism.

4. The method for expediting defect detection and burning of claim 1, wherein said step of seeking a target write-in area, and reading data stored in said target write-in area, and detecting if said data fall in an unreliable area makes use of physical properites of said optical disc to determine said unreliable area.

5. The method for expediting defect detection and burning of claim 1, wherein said spare area exists in a continuous form or a discrete form in any unwritten area of said optical disc.

6. The method for expediting defect detection and burning of claim 1, further comprising a step of determining whether or not said desired burning area already has existing data.

7. A method for expediting defect detection and burning, being used in a blank optical disc, said method comprising the steps of:
(a) seeking a target write-in area and writing verification data;
(b) seeking said target write-in area, reading said verification data, and detecting if said verification data fall in an unreliable data;
(c) seeking said target write-in area and writing desired burning data;
(d) determining whether or not said unreliable area exists;
(e) writing said desired burning data stored in said unreliable area into a spare area, if said unreliable area as described in step (d) exists; and
(f) determining whether or not burning of all data is completed, and repeating steps (b) to (f) until the burning of all data is completed, if the burning of all data is not completed.

8. The method for expediting defect detection and burning of claim 7, wherein said step of seeking said target write-in area and writing verification data is a process of formatting said optical disc.

9. The method for expediting defect detection and burning of claim 7, wherein said step of seeking a target write-in area, reading data stored in said target write-in area, and detecting if said data fall in an unreliable area makes use of the readability of read data to determine said unreliable area.

10. The method for expediting defect detection and burning of claim 7, wherein said step of seeking a target write-in area, and reading data stored in said target write-in area, and detecting if said data fall in an unreliable area determines said unreliable area by an original error of read data being larger than a critical value, said original error being obtained from an error correction mechanism.

11. The method for expediting defect detection and burning of claim 7, wherein said step of seeking a target write-in area, reading data stored in said target write-in area, and detecting if said data fall in an unreliable area makes use of physical properites of said optical disc to determine said unreliable area.

12. The method for expediting defect detection and burning of claim 7, wherein said spare area exists in a continuous form or a discrete form in any unwritten area of said optical disc.

13. The method for expediting defect detection and burning of claim 7, further comprising a step of determining whether or not said desired burning area already has existing data.

14. A method for expediting defect detection and burning, being used in an optical disc having burned data, said method comprising the steps of:
(a) seeking a target write-in area, reading data stored in said target write-in area, and detecting if said data fall in an unreliable area;
(b) seeking said target write-in area and writing a desired burning data;
(c) determining whether or not said unreliable area exists;
(d) carrying out a reconfirmation of said burned data and writing said burned data into a spare area, if said unreliable area as described in step (c) exists;
(e) determining whether or not burning of all data is completed, and repeating steps (a) to (e) until the burning of all data is completed, if the burning of all data is not completed.

15. The method for expediting defect detection and burning of claim 14, wherein said step of carrying out a reconfirmation of said burned data and writing said burned data into a spare area further comprises:
seeking said unreliable area, and reading burned data, and detecting whether or not said burned data is unreliable; and
writing said desired burning data stored in said unreliable area into a spare area.

16. The method for expediting defect detection and burning of claim 14, wherein said step of seeking a target write-in area, reading data stored in said target write-in area, and detecting if said data fall in an unreliable area makes use of the readability of read data to determine said unreliable area.

17. The method for expediting defect detection and burning of claim 14, wherein said step of seeking a target write-in area, reading data stored in said target write-in area, and detecting if said data fall in an unreliable area determines said unreliable area by an original error of read data being larger than a critical value and said original error being obtained from an error correction mechanism.

18. The method for expediting defect detection and burning of claim 14, wherein said step of seeking a target write-in area, reading data stored in said target write-in area, and detecting if said data fall in an unreliable area makes use of the physical properties of said optical disc to determine said unreliable area.

19. The method for expediting defect detection and burning of claim 14, wherein said spare area exists in a continuous form or a discrete form in any unwritten area of said optical disc.

20. The method for expediting defect detection and burning of claim 14, further comprising a step of determining whether or not said desired burning area already has existing data.

21. A method for expediting defect detection and burning, being used in a blank optical disc, said method comprising the steps of:
(a) seeking a target write-in area and writing verification data;
(b) seeking said target write-in area, reading said verification data, and detecting if said verification data lie in unreliable data;
(c) seeking said target write-in area and writing desired burning data;
(d) determining whether or not said unreliable area exists;
(e) writing said desired burning data stored in said unreliable area into a spare area, if said unreliable area as described in step (d) exists; and
(f) determining whether or not burning of all data is completed, and repeating steps (b) to (f) until the burning of all data is completed, if the burning of all data is not completed.

22. The method for expediting defect detection and burning of claim 21, wherein said step of carrying out a reconfirmation of said burned data and writing said burned data into a spare area further comprises:
seeking said unreliable area, reading burned data, and detecting whether or not said burned data is unreliable; and
writing said desired burning data stored in said unreliable area into a spare area.

23. The method for expediting defect detection and burning of claim 21, wherein said step of seeking said target write-in area and writing in verification data is a process of formatting said optical disc.

24. The method for expediting defect detection and burning of claim 21, wherein said step of seeking a target write-in area, reading data stored in said target write-in area, and detecting if said data fall in an unreliable area makes use of the readability of read data to determine said unreliable area.

25. The method for expediting defect detection and burning of claim 21, wherein said step of seeking a target write-in area, reading data stored in said target write-in area, and detecting if said data fall in an unreliable area determines said unreliable area by the original error of read data being larger than a critical value and said original error being obtained from an error correction mechanism.

26. The method for expediting defect detection and burning of claim 21, wherein said step of seeking a target write-in area, reading data stored in said target write-in area, and detecting if said data fall in an unreliable area makes use of the physical properties of said optical disc to determine said unreliable area.

27. The method for expediting defect detection and burning of claim 21, wherein said spare area exists in a continuous form or a discrete form in any unwritten area of said optical disc.

28. The method for expediting defect detection and burning of claim 21, further comprising a step of determining whether or not said desired burning area already has existing data.
